(19) United States
(12) Patent Application Publication
(10) Pub. No.: US 2025/0300133 A1
(43) Pub. Date: Sep. 25, 2025

(54) 3D STACKING WITH THROUGH-MOLD CAVITY FOR THERMAL MANAGEMENT

(71) Applicant: QUALCOMM Incorporated, San Diego, CA (US)

(72) Inventors: Yujen CHEN, Taichung (TW); Yangyang SUN, San Diego, CA (US)

(21) Appl. No.: 18/609,610

(22) Filed: Mar. 19, 2024

(51) Int. Cl. H01L 25/065; H01L 23/00; H01L 23/48

(52) U.S. Cl. CPC H01L 25/0657; H01L 23/481; H01L 24/13; H01L 2224/13147; H01L 2225/06541; H01L 2924/3511

(57) ABSTRACT

Disclosed are stacked packages in which through-mold cavities are formed within the mold and filled with thermally conductive pillars. The pillars are thermally coupled to a die. In this way, the heat from the die can be conducted away.

### BACKGROUND OF THE DISCLOSURE

### 1. Field of the Disclosure

This disclosure relates generally to die packages or modules, and more specifically, but not exclusively, to 3DIC packages/modules that include a through-mold cavity for thermal management and fabrication techniques thereof.

### 2. Description of the Related Art

Integrated circuit (IC) technology has achieved great strides in advancing computing power through miniaturization of active components. In current 5G and WiFi6 radio frequency (RF) frontend packages/modules, radio-frequency integrated circuit (RFIC) chips such as switches (SW), low noise amplifiers (LNA), power amplifiers (PA), digital amplifiers (DA), filters, etc. are placed side-by-side in a package, e.g., for an RF frontend module. For three-dimensional (3D) stacking, two or more dies of different sizes are stacked, and the mismatched die area are usually filled by molding compound or a dummy silicon is added. Unfortunately, both have limitations when it comes to thermal management. Accordingly, there is a need for systems, apparatus, and methods that overcome the deficiencies of conventional stacked packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary stacked package is disclosed. The stacked package may comprise a first die with one or more through-silicon-vias (TSV) extending from lower to upper surfaces of the first die. The stacked package may also comprise a second die on the first die. The first and second dies may exchange electrical signals with each other through the TSVs. The stacked package may further comprise a mold on the first die. The mold may encapsulate sides of the second die. The stacked package may yet comprise one or more through-mold cavities formed within the mold. The stacked package may yet further comprise one or more thermal pillars formed in the one or more through-mold cavities. The one or more thermal pillars may be thermally coupled with the first die.

A method of fabricating an exemplary stacked package is disclosed. The method may comprise providing a first die with one or more through-silicon-vias (TSV) extending from lower to upper surfaces of the first die. The method may also comprise providing a second die on the first die. The first and second dies may exchange electrical signals with each other through the TSVs. The method may further comprise forming a mold on the first die. The mold may encapsulate sides of the second die. The method may yet comprise forming one or more through-mold cavities within the mold. The method may yet further comprise forming one or more thermal pillars in the one or more through-mold cavities. The one or more thermal pillars may be thermally coupled with the first die.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross section of an example of a conventional stacked package.

FIG. 2A illustrates a cross section of an example of a stacked package in accordance with one or more aspects of the disclosure.

FIG. 2B illustrates a top view of the example stacked package of FIG. 2A.

FIGS. 3A-3D illustrate examples of stages of one process of fabricating a stacked package in accordance with one or more aspects of the disclosure.

FIGS. 4A-4F illustrate examples of stages of another process of fabricating a stacked package in accordance with one or more aspects of the disclosure.

FIGS. 5-8 illustrate flow charts of example methods of manufacturing a stacked package in accordance with at one or more aspects of the disclosure.

FIG. 9 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are stacked packages and methods for fabricating the same. In an aspect, the stacked package may comprise a first die, a second die, a mold, one or more through-mold cavities, and one or more thermal pillars. One or more through-silicon-vias (TSV) may extend from lower to upper surfaces of the first die. The second die may be on the first die. The first and second dies may exchange electrical signals with each other through the TSVs. The mold may be on the first die, and may encapsulate sides of the second die. The one or more through-mold cavities may be formed within the mold and the one or more thermal pillars may be formed in the one or more through-mold cavities. The one or more thermal pillars may be thermally coupled with the first die. In this way, heat may be carried away from the first die.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

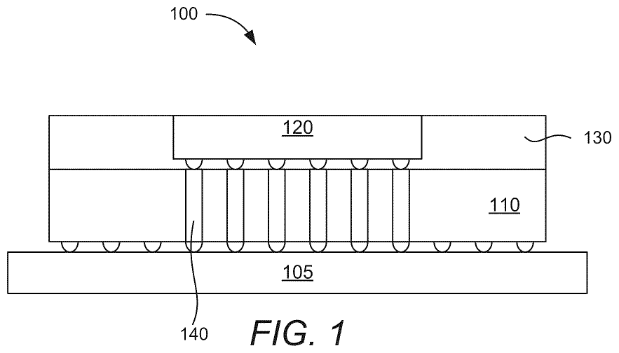

As indicated above, for three-dimensional (3D) stacking, two or more dies of different sizes are stacked. FIG. 1 illustrates an example of a conventional stacked package 100 that includes a first die 110 on a substrate 105, and a second die 120 on the first die 110. There are through-silicon-vias (TSV) 140 that extend from lower to upper surfaces of the first die 110. The mold 130 is on the first die 110 and encapsulates the second die 120.

When the dies of differing sizes are stacked such as the first and second dies 110, 120, the mismatched die area are usually filled by molding compound or a dummy silicon (Si) is added. Unfortunately, both have limitations when it comes to thermal management. Dummy Si size is limited to >2.5 mm per side due to dicing/attachment constraint. There is a lack of flexibility to all the area with the dummy Si.

Filling with molding compound creates other issues. First, molding at the top side can cause thermal concern. Also, thermo-compression (TC) bonder heat transfer through the molding compound can become an issue. Second, molded wafers can have wafer warpage issues. This can cause, among other things, challenges to wafer probes. Third, high temperature (HT) warpage can be worse due to the mold compound. This can cause non-wet conditions during die bonding, even with TC bonding.

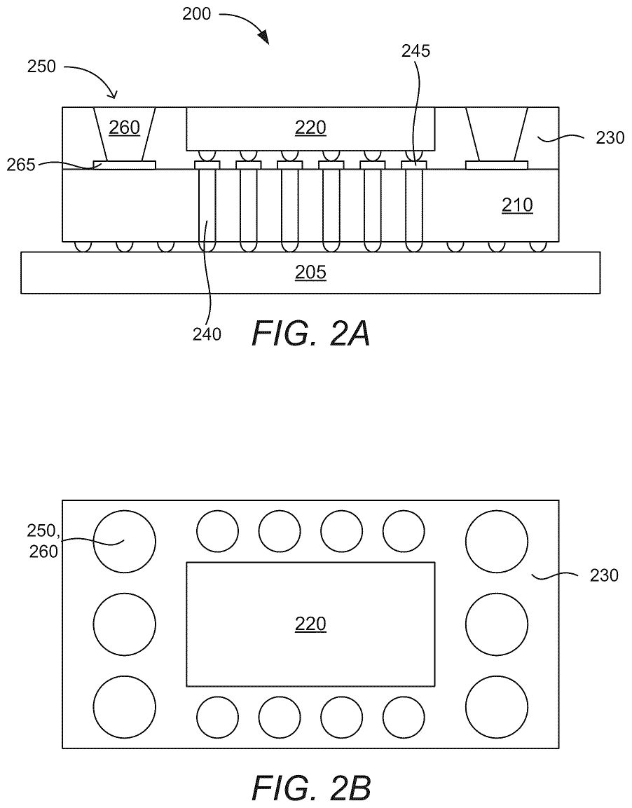

To address these and other issues of the conventional stacked package, it is proposed to increase heat removing capability by providing a thermally conductive path from the heat generating dies. FIG. 2A illustrates an example of a stacked package 200 in accordance with one or more aspects of the disclosure.

The stacked package 200 may include a first die 210 with one or more through-silicon-vias (TSV) 240 extending from lower to upper surfaces of the first die 210. In an aspect, the first die 210 may be provided on a substrate 205.

The stacked package 200 may also include a second die 220 on the first die 210. The first and second dies 210, 220 exchange electrical signals with each other through the TSVs 240. That is, they may communicate with each other through the TSVs 240.

In FIG. 2A, it may be assumed that the first and second dies 210, 220 are of different sizes. For example, the second die 220 may be smaller than the first die 210. Thus, a mold 230 may be formed on the first die 210. As seen, the mold 230 may encapsulate sides of the second die 220.

One or more through-mold cavities 250 may be formed within the mold 230. Further, one or more thermal pillars 260 may be formed in the one or more through-mold cavities 250. The one or more thermal pillars 260 may be thermally coupled with the first die 210 (e.g., with the upper surface of the first die 210). The one or more thermal pillars 260 may be formed from thermally conductive metals such as copper (Cu).

One or more thermal pads 265 may be formed on the first die 210 within the mold 230. The one or more thermal pads 265 may be between the corresponding one or more thermal pillars 260 and the first die 210, and the one or more thermal pads 265 may be thermally coupled with the corresponding one or more thermal pillars 260. Some or all (i.e., at least one) thermal pads 265 may be in direct with the corresponding some or all thermal pillars 260 and with the upper surface of the first die 210. The thermal pads 265 may also be formed from thermally conductive metals such as Cu.

There are at least the following technical advantages:
The thermal pads on the upper surface of the first die→improve 3D integrated circuit (3DIC) thermal concern.
Through-mold cavities (less mold volume)→reduce wafer warpage for probe and reduce die warpage for die bonding.
Thermal pillars in the through-mold cavities→allow better thermal transfer than original mold compound→enable TC bonding and improve 3DIC thermal concern.
Drill size (e.g., diameter of thermal pillars) is flexible, e.g., 50 μm or more, flexibility in fitting into varies stacking floor plans.

FIG. 2B illustrates a top view of the stacked package 200. The one or more through-mold cavities 250 (and hence the one or more thermal pillars 260) need not all be of the same size. That is, at least two thermal pillars 260 may be of different sizes.

Also, in FIG. 2B, the thermal pillars 260 are shown to be circular. However, this is not a limitation. The thermal pillars 260 may take on other shapes (such as squares, not shown). Also, the one or more through-mold cavities 250 (and hence the one or more thermal pillars 260) need not all be of the same shape. That is, at least two thermal pillars 260 may be of different shapes (not shown).

There can also be one or more TSV pads 245 on the first die 210 within the mold 230. The one or more TSV pads 245 may be between the corresponding one or more TSVs 240 and the second die 220. The one or more TSV pads 245 may be electrically coupled to the corresponding one or more TSVs 240. For example, the one or more TSV pads 245 may be in direct contact with the corresponding one or more TSVs 240. The one or more TSV pads 245 may be formed from electrically conductive metal such as Cu.

In an aspect, upper surfaces of the second die 220, the mold 230, and the one or more thermal pillars 260 may be coplanar or substantially coplanar, e.g., within tolerances of a planarizing process.

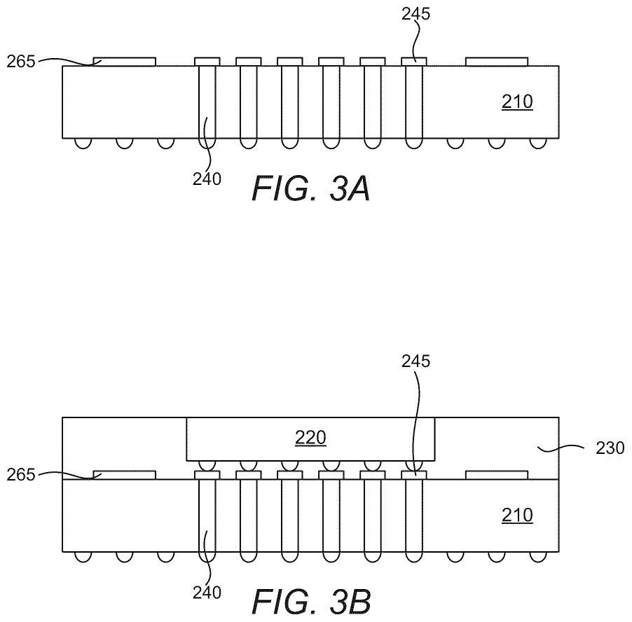

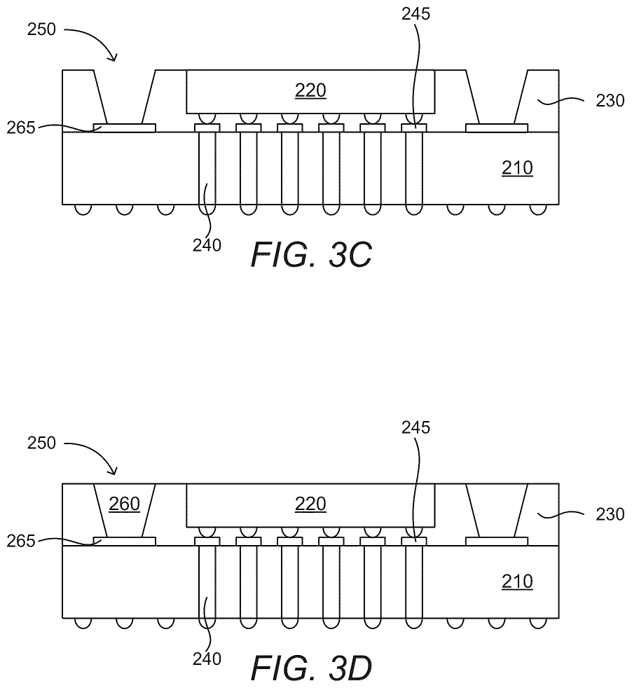

FIGS. 3A-3D illustrate examples of stages of one process of fabricating a stacked package—such as the stacked package 200—in accordance with at one or more aspects of the disclosure. The process illustrated in FIGS. 3A-3D may be referred to as a laser drilling process.

FIG. 3A illustrates a stage in which the TSVs 240 of the first die 210 are revealed. Then a backside metallization can take place to form the TSV pads 245 and the thermal pads 265 on the upper surface of the first die 210.

FIG. 3B illustrates a stage in which the second die 220 is provided on the first die 210, and molding process is performed to form the mold 230.

FIG. 3C illustrates a stage in which laser drilling is performed to form the through-mold cavities 250 in the mold 230 corresponding to the areas of the thermal pads 265.

FIG. 3D illustrates a stage in which the through-mold cavities 250 are filled with thermally conductive material, such as Cu, to form the thermal pillars 260.

Note that polishing and/or grinding may be performed in any of the stages 3B-3D so that the upper surfaces of the second die 220, the mold 230, and the one or more thermal pillars 260 are coplanar or substantially coplanar.

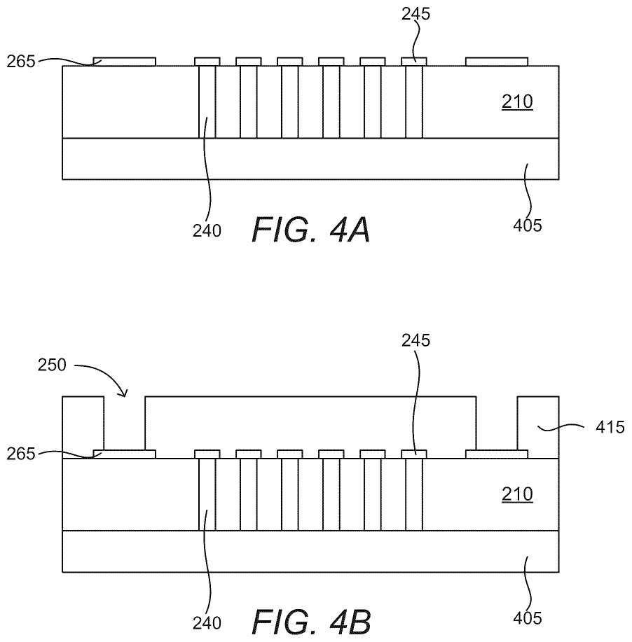

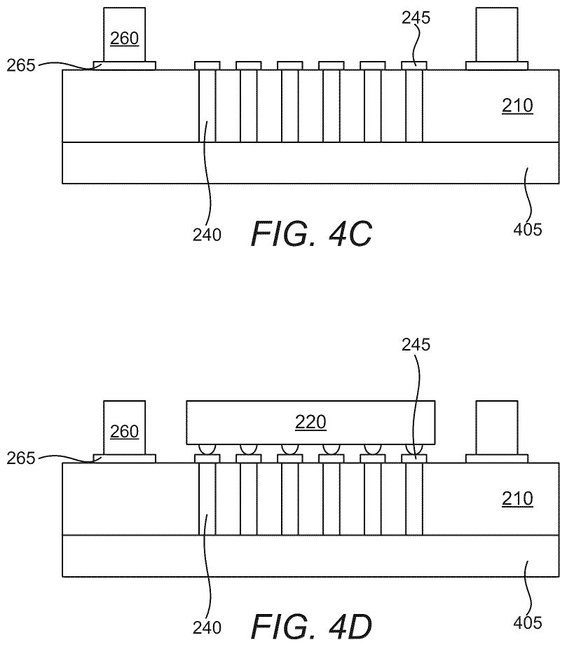

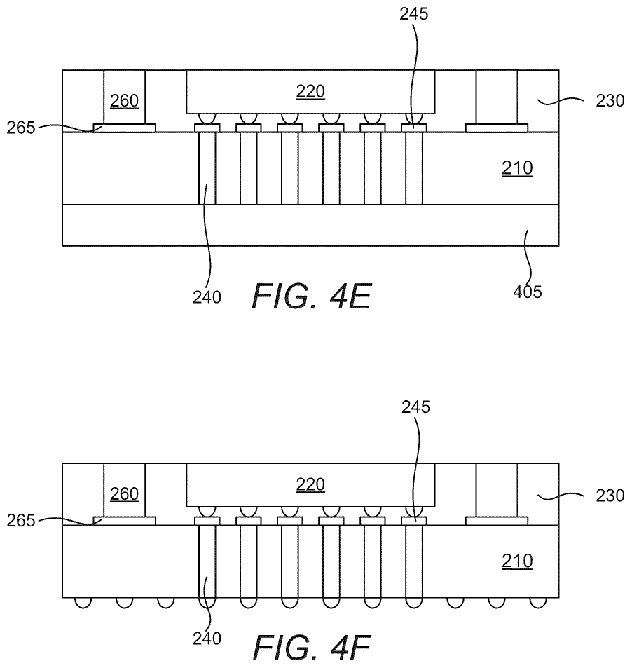

FIGS. 4A-4F illustrate examples of stages of another process of fabricating a stacked package—such as the stacked package 200—in accordance with at one or more aspects of the disclosure. The process illustrated in FIGS. 3A-3D may be referred to as a patterning process.

FIG. 4A illustrates a stage in which the TSVs 240 of the first die 210 are revealed. Then a backside metallization can take place to form the TSV pads 245 and the thermal pads 265 on the upper surface of the first die 210. Note that the first die 210 may be attached to a carrier 405.

FIG. 4B illustrates a stage in which a patternable material 415 (e.g., photo resist (PR)) is deposited on the first die 210, on the thermal pads 265, and on the TSV pads 245. Thereafter, the patternable material 415 is patterned to form holes that expose the thermal pads 265.

FIG. 4C illustrates a stage in plating with conductive metal is performed to fill the holes of the patternable material 415 to form the thermal pillars 260. Thereafter, the patternable material 415 is removed.

FIG. 4D illustrates a stage in which the second die 220 is attached on the first die 210, and in particular to the TSV pads 245.

FIG. 4E illustrates a stage in which a molding compound may be deposited to form the mold 230.

FIG. 4F illustrates a stage in which the carrier 405 is removed.

Note that polishing and/or grinding may be performed in any of the stages 4E-4F so that the upper surfaces of the second die 220, the mold 230, and the one or more thermal pillars 260 are coplanar or substantially coplanar.

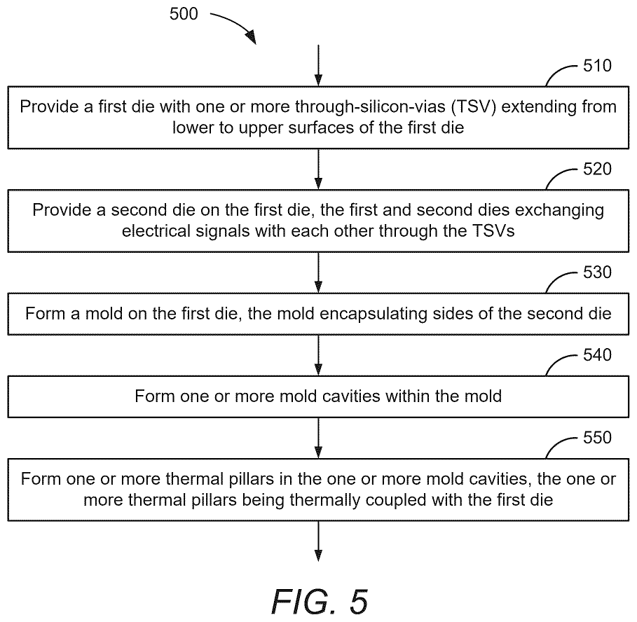

FIG. 5 illustrates a flow chart of an example method 500 of fabricating a stacked package, such as the stacked package 200, in accordance with at one or more aspects of the disclosure.

In block 510, a first die 210 may be provided. There may be one or more through-silicon-vias (TSV) 240 extending from lower to upper surfaces of the first die 210.

In block 520, a second die 220 may be provided on the first die 210. The first and second dies 210, 220 may exchange electrical signals with each other through the TSVs 240.

In block 530, a mold 230 may be formed on the first die 210. The mold 230 may encapsulate sides of the second die 220.

In block 540, one or more through-mold cavities 250 may be formed within the mold 230.

In block 550, one or more thermal pillars 260 may be formed in the one or more through-mold cavities 250. The one or more thermal pillars 260 may be thermally coupled with the first die 210.

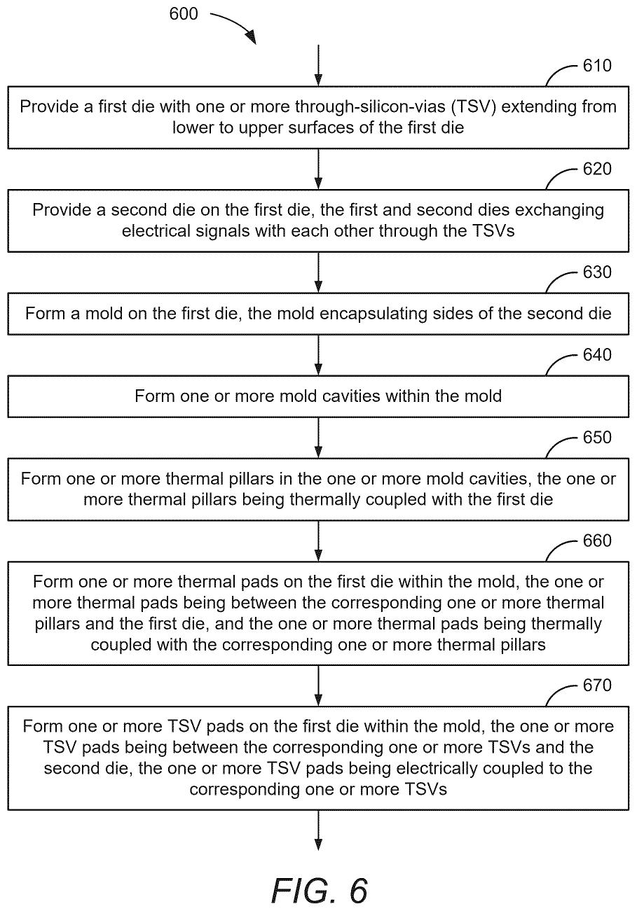

FIG. 6 illustrates a flow chart of an example method 600 of fabricating a stacked package, such as the stacked package 200 in accordance with at one or more aspects of the disclosure. FIG. 6 may be viewed as being more comprehensive than FIG. 5.

Block 610 may be similar to block 510. That is, in block 610, a first die 210 may be provided. There may be one or more through-silicon-vias (TSV) 240 extending from lower to upper surfaces of the first die 210.

Block 620 may be similar to block 520. That is, in block 620, a second die 220 may be provided on the first die 210. The first and second dies 210, 220 may exchange electrical signals with each other through the TSVs 240.

Block 630 may be similar to block 530. That is, in block 630, a mold 230 may be formed on the first die 210. The mold 230 may encapsulate sides of the second die 220.

Block 640 may be similar to block 540. That is, in block 640, one or more through-mold cavities 250 may be formed within the mold 230.

Block 650 may be similar to block 550. That is, in block 650, one or more thermal pillars 260 may be formed in the one or more through-mold cavities 250. The one or more thermal pillars 260 may be thermally coupled with the first die 210.

In block 660, one or more thermal pads 265 may be formed on the first die 210 within the mold 230. The one or more thermal pads 265 may be between the corresponding one or more thermal pillars 260 and the first die 210. Also, the one or more thermal pads 265 may be thermally coupled with the corresponding one or more thermal pillars 260.

In block 670, one or more TSV pads 245 may be formed on the first die 210 within the mold 230. The one or more TSV pads 245 may be between the corresponding one or more TSVs 240 and the second die 220. The one or more TSV pads 245 may be electrically coupled to the corresponding one or more TSVs 240.

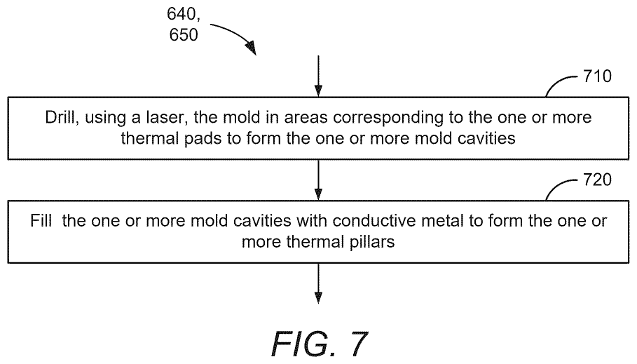

FIG. 7 illustrates a flow chart of a process to implement blocks 640, 650 (and hence blocks 540, 550). The flow chart of FIG. 7 may correspond to the laser drilling stages illustrated in FIGS. 3A-3D.

In block 710, the mold 230 may be drilled, using a laser, in areas corresponding to the one or more thermal pads 265 to form the one or more through-mold cavities 250.

In block 720, the one or more through-mold cavities 250 with conductive metal to form the one or more thermal pillars 260.

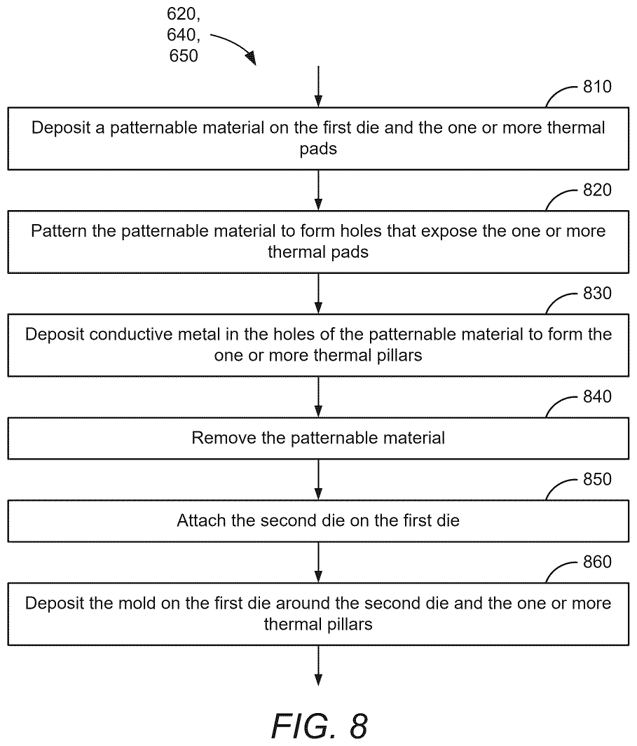

FIG. 8 illustrates a flow chart of a process to implement blocks 620, 640, 650 (and hence blocks 520, 540, 550). The flow chart of FIG. 8 may correspond to the patterning process stages illustrated in FIGS. 4A-4F.

In block 810, a patternable material 415 may be deposited on the first die 210 and the one or more thermal pads 265.

In block 820, the patternable material 415 may be patterned to form holes that expose the one or more thermal pads 265.

In block 830, conductive metal may be plated in the holes of the patternable material 415 to form the one or more thermal pillars 260.

In block 840, the patternable material 415 may be removed.

In block 850, the second die 220 may be attached on the first die 210.

In block 860, the mold 230 may be deposited on the first die 210 around the second die 220 and on the one or more thermal pillars 260.

The following should be noted regarding the flow indicated in FIGS. 4-8. Unless otherwise indicated, the flow of blocks do not necessarily limit the ordering in which the blocks may be performed. In other words, the blocks may be performed in any order that is logical.

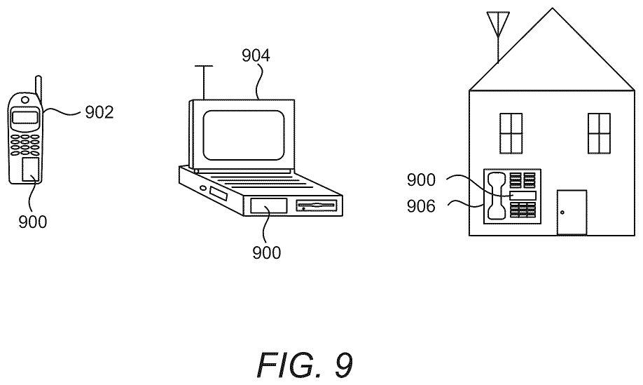

FIG. 9 illustrates various electronic devices 900 that may be integrated with any of the aforementioned stacked package in accordance with various aspects of the disclosure. For example, a mobile phone device 902, a laptop computer device 904, and a fixed location terminal device 906 may each be considered generally user equipment (UE) and may include one or more stacked packages (e.g., stacked package 200) as described herein. The devices 902, 904, 906 illustrated in FIG. 9 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A stacked package, comprising: a first die with one or more through-silicon-vias (TSV) extending from lower to upper surfaces of the first die; a second die on the first die, the first and second dies exchanging electrical signals with each other through the TSVs; a mold on the first die, the mold encapsulating sides of the second die; one or more through-mold cavities formed within the mold; and one or more thermal pillars formed in the one or more through-mold cavities, the one or more thermal pillars being thermally coupled with the first die.

Clause 2: The stacked package of clause 1, wherein the one or more thermal pillars are formed from copper (Cu).

Clause 3: The stacked package of any of clauses 1-2, further comprising: one or more thermal pads on the first die within the mold, the one or more thermal pads being between the corresponding one or more thermal pillars and the first die, and the one or more thermal pads being thermally coupled with the corresponding one or more thermal pillars.

Clause 4: The stacked package of clause 3, wherein at least one thermal pad is in direct contact with the corresponding at least one thermal pillar and in direct contact with an upper surface of the first die.

Clause 5: The stacked package of any of clauses 1-4, wherein a diameter of at least one thermal pillar is 50 μm or greater.

Clause 6: The stacked package of any of clauses 1-5, wherein at least two thermal pillars are of different sizes.

Clause 7: The stacked package of any of clauses 1-6, further comprising: one or more TSV pads on the first die within the mold, the one or more TSV pads being between the corresponding one or more TSVs and the second die, the one or more TSV pads being electrically coupled to the corresponding one or more TSVs.

Clause 8: The stacked package of any of clauses 1-7, wherein upper surfaces of the second die, the mold, and the one or more thermal pillars are coplanar.

Clause 9: The stacked package of any of clauses 1-8, further comprising: a substrate on a lower surface of the first die.

Clause 10: The stacked package of any of clauses 1-9, wherein the stacked package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 11: A method of fabricating a stacked package, the method comprising: providing a first die with one or more through-silicon-vias (TSV) extending from lower to upper surfaces of the first die; providing a second die on the first die, the first and second dies exchanging electrical signals with each other through the TSVs; forming a mold on the first die, the mold encapsulating sides of the second die; forming one or more through-mold cavities within the mold; and forming one or more thermal pillars in the one or more through-mold cavities, the one or more thermal pillars being thermally coupled with the first die.

Clause 12: The method of clause 11, wherein the one or more thermal pillars are formed from copper (Cu).

Clause 13: The method of any of clauses 11-12, further comprising: forming one or more thermal pads on the first die within the mold, the one or more thermal pads being between the corresponding one or more thermal pillars and the first die, and the one or more thermal pads being thermally coupled with the corresponding one or more thermal pillars.

Clause 14: The method of clause 13, wherein forming the one or more through-mold cavities and forming the one or more thermal pillars in the one or more through-mold cavities comprise: drilling, using a laser, the mold in areas corresponding to the one or more thermal pads to form the one or more through-mold cavities; and filling the one or more through-mold cavities with conductive metal to form the one or more thermal pillars.

Clause 15: The method of clause 13, wherein providing the second die, forming the one or more through-mold cavities, and forming the one or more thermal pillars in the one or more through-mold cavities comprise: depositing a patternable material on the first die and the one or more thermal pads; patterning the patternable material to form holes that expose the one or more thermal pads; plating conductive metal in the holes of the patternable material to form the one or more thermal pillars; removing the patternable material; attaching the second die on the first die; and depositing the mold on the first die around the second die and on the one or more thermal pillars.

Clause 16: The method of any of clauses 13-15, wherein at least one thermal pad is in direct contact with the corresponding at least one thermal pillar and in direct contact with an upper surface of the first die.

Clause 17: The method of any of clauses 11-16, wherein a diameter of at least one thermal pillar is 50 μm or greater.

Clause 18: The method of any of clauses 11-17, wherein at least two thermal pillars are of different sizes.

Clause 19: The method of any of clauses 11-18, further comprising: forming one or more TSV pads on the first die within the mold, the one or more TSV pads being between the corresponding one or more TSVs and the second die, the one or more TSV pads being electrically coupled to the corresponding one or more TSVs.

Clause 20: The method any of clauses 11-19, wherein upper surfaces of the second die, the mold, and the one or more thermal pillars are coplanar.

Clause 21: The method of any of clauses 11-20, further comprising: forming a substrate on a lower surface of the first die.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A stacked package, comprising:
a first die with one or more through-silicon-vias (TSV) extending from lower to upper surfaces of the first die;
a second die on the first die, wherein the first die and the second die are configured to exchange electrical signals with each other through the TSVs;
a mold on the first die, wherein the mold encapsulates sides of the second die;
one or more through-mold cavities formed within the mold; and
one or more thermal pillars formed in the one or more through-mold cavities, the one or more thermal pillars being thermally coupled with the first die.

2. The stacked package of claim 1, wherein the one or more thermal pillars are formed from copper (Cu).

3. The stacked package of claim 1, further comprising:
one or more thermal pads on the first die within the mold, the one or more thermal pads being between a corresponding one or more thermal pillars and the first die, wherein the one or more thermal pads are thermally coupled with the corresponding one or more thermal pillars.

4. The stacked package of claim 3, wherein at least one thermal pad is in direct contact with a corresponding at least one thermal pillar and in direct contact with an upper surface of the first die.

5. The stacked package of claim 1, wherein a diameter of at least one thermal pillar is 50 μm or greater.

6. The stacked package of claim 1, wherein at least two thermal pillars are of different sizes.

7. The stacked package of claim 1, further comprising:
one or more TSV pads on the first die within the mold, the one or more TSV pads being between a corresponding one or more TSVs and the second die, the one or more TSV pads being electrically coupled to the corresponding one or more TSVs.

8. The stacked package of claim 1, wherein upper surfaces of the second die, the mold, and the one or more thermal pillars are coplanar.

9. The stacked package of claim 1, further comprising:
a substrate on a lower surface of the first die.

10. The stacked package of claim 1, wherein the stacked package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

11. A method of fabricating a stacked package, the method comprising:
providing a first die with one or more through-silicon-vias (TSV) extending from lower to upper surfaces of the first die;
providing a second die on the first die, wherein the first die and the second die are configured to exchange electrical signals with each other through the TSVs;
forming a mold on the first die, wherein the mold encapsulates sides of the second die;
forming one or more through-mold cavities within the mold; and
forming one or more thermal pillars in the one or more through-mold cavities, the one or more thermal pillars being thermally coupled with the first die.

12. The method of claim 11, wherein the one or more thermal pillars are formed from copper (Cu).

13. The method of claim 11, further comprising:
forming one or more thermal pads on the first die within the mold, the one or more thermal pads being between a corresponding one or more thermal pillars and the first die, and the one or more thermal pads being thermally coupled with the corresponding one or more thermal pillars.

14. The method of claim 13, wherein forming the one or more through-mold cavities and forming the one or more thermal pillars in the one or more through-mold cavities comprise:
drilling, using a laser, the mold in areas corresponding to the one or more thermal pads to form the one or more through-mold cavities; and
filling the one or more through-mold cavities with conductive metal to form the one or more thermal pillars.

15. The method of claim 13, wherein providing the second die, forming the one or more through-mold cavities, and forming the one or more thermal pillars in the one or more through-mold cavities comprise:
depositing a patternable material on the first die and the one or more thermal pads;
patterning the patternable material to form holes that expose the one or more thermal pads;
plating conductive metal in the holes of the patternable material to form the one or more thermal pillars;
removing the patternable material;
attaching the second die on the first die; and
depositing the mold on the first die around the second die and on the one or more thermal pillars.

16. The method of claim 13, wherein at least one thermal pad is in direct contact with a corresponding at least one thermal pillar and in direct contact with an upper surface of the first die.

17. The method of claim 11, wherein a diameter of at least one thermal pillar is 50 μm or greater.

18. The method of claim 11, wherein at least two thermal pillars are of different sizes.

19. The method of claim 11, further comprising:
forming one or more TSV pads on the first die within the mold, the one or more TSV pads being between a corresponding one or more TSVs and the second die, the one or more TSV pads being electrically coupled to the corresponding one or more TSVs.

20. The method of claim 11, wherein upper surfaces of the second die, the mold, and the one or more thermal pillars are coplanar.
